(19) United States
(12) Patent Application Publication
(10) Pub. No.: US 2026/0054349 A1
(43) Pub. Date: Feb. 26, 2026

(54) EDGE ZONE COATING REMOVAL APPARATUS AND METHOD

(71) Applicant: Yield Engineering Systems, Inc., Fremont, CA (US)

(72) Inventors: Krishna Channaiah, Bangalore (IN); Antin Shibu, Coimbatore (IN); Arun Karthick, Erode (IN); Roger Hamamjy, San Jose, CA (US); Shiv Kumar, San Jose, CA (US); Laxman Murugesh, Livermore, CA (US); Anthony Coniglio, Fremont, CA (US)

(73) Assignee: Yield Engineering Systems, Inc., Fremont, CA (US)

(21) Appl. No.: 18/811,061

(22) Filed: Aug. 21, 2024

(51) Int. Cl. B24C 1/04; B24C 1/08; B24C 3/32; B24C 5/04; B24C 7/00

(52) U.S. Cl. CPC B24C 1/04; B24C 1/086; B24C 3/32; B24C 5/04; B24C 7/0084

(57) ABSTRACT

An apparatus to remove a coating from an edge of a substrate includes a vacuum chuck assembly and a nozzle assembly. The vacuum chuck assembly is configured to support the substrate using suction. The nozzle assembly includes a nozzle head with a pair of nozzle tips configured to direct an angled liquid stream on a surface of the substrate. An annular duct around each nozzle tip discharges a pressurized gas to form a gas shroud around the angled liquid stream.

### TECHNICAL FIELD

The present disclosure relates to an apparatus and a method for the removal of one or more coatings from the edge zone of a substrate.

### BACKGROUND

The fabrication process of semiconductor and photonic devices is composed of many sequential steps to produce complete electrical and/or photonic circuits on a wafer or a panel of a suitable material (e.g., semiconductor wafers, glass panels, etc.). Defects of any source introduced during the fabrication process reduces yield of the resulting devices. A common source of defects are the residues of coatings (e.g., deposited films, etc.) on the edge(s) of a substrate that the devices are formed on. These coating residues on the edge may be the result of incomplete removal of a coating used in the fabrication process from the edge. The substrate edge may be part of (or form), for example, the substrate bevel, substrate edge exclusion zone, handling area, etc. For example, portions of the residual coatings (e.g., metal films such as Ti, Cu, Pd, Ni, etc.) retained on the substrate may peel or delaminate during subsequent processing (e.g., deposition, heating, etc.) of the substrate and cause defects in the resulting device. Thus, processes to satisfactorily remove the coatings from the edge(s) of a substrate used in semiconductor fabrication are important.

Currently there are limited ways to remove coatings from a substrate edge. One current method uses plasma or laser ablation where a suitable laser beam (e.g., a YAG laser) is focused on the coated substrate to ablate the coating. In addition to requiring multiple passes for satisfactory coating removal, such a removal method may also result in redeposition of debris on coated surfaces (requiring subsequent cleaning steps) and result in defects. Furthermore, the metal layer edges post etching may not be as straight as desired when using laser and plasma ablation. Additionally, laser and plasma ablation tools are expensive and may require good ventilation and other protection systems for safe use. Moreover, with substrates becoming thinner (e.g., 200-250 micron), traditional laser coating removal methods risk breaking fragile panels. Additionally, some coatings (such as, for example, copper, titanium, etc.) are difficult to remove using a laser because of the large amount of energy needed for their removal.

The apparatus and methods of the current disclosure may alleviate at least some of the above-described deficiencies. However, the scope of the current disclosure is defined by the claims and not by its ability to solve any problem.

### SUMMARY

Embodiments of an apparatus for coating removal and method of coating removal are disclosed.

In one embodiment, an apparatus to remove at least a portion of a coating from an edge of a substrate is disclosed. The apparatus includes a vacuum chuck assembly configured to support the substrate and a nozzle assembly. The vacuum chuck assembly may include a plurality of vacuum cups configured to hold the substrate using suction. The nozzle assembly may include one or more nozzle heads. Each nozzle head may include a body having a cavity. The cavity may be configured to receive the edge of the substrate therein. A suction cup may be positioned within the cavity. The suction cup may be configured to be coupled to a vacuum pump. A pair of nozzle tips is supported on the body and positioned on opposite sides of the cavity. The pair of nozzle tips may each be inclined towards the suction cup and configured to direct an angled stream of a liquid on a surface of the substrate received in the cavity. An annular duct may be defined around each nozzle tip of the pair of nozzle tips. The annular duct may be configured to discharge a pressurized gas to form a gas shroud around the angled stream of liquid.

In another embodiment, an apparatus to remove at least a portion of a coating from an edge of a substrate is disclosed. The apparatus may include a vacuum chuck assembly configured to support the substrate and a nozzle assembly that includes a plurality of nozzle heads arranged side-to-side. The vacuum chuck assembly may include a plurality of radially extending arms equally spaced apart from each other. The plurality of radially extending arms may include a first set of arms and a second set of arms. A plurality vacuum cups may be coupled to the first set of arms. The plurality of vacuum cups may be configured to hold the substrate using suction. A plurality of shower-heads may be coupled to the second set of arms. The plurality of shower-heads may be positioned radially outwards of the plurality vacuum cups and may each be configured to discharge pressurized air under a corner region of the substrate. Each nozzle head of the nozzle assembly may include a body having a cavity. The cavity may be configured to receive the edge of the substrate therein. A suction cup may be positioned within the cavity and may be configured to be coupled to a vacuum pump. A pair of nozzle tips may be positioned on opposite sides of the cavity. The pair of nozzle tips may each be (i) inclined towards the suction cup and make an angle between about 30-60 degrees with a surface of the substrate, and (ii) configured to direct an angled stream of a liquid on a surface of the substrate received in the cavity. An annular duct may be defined around each nozzle tip of the pair of nozzle tips. The annular duct may be configured to discharge a pressurized gas to form a gas shroud around the angled stream of the liquid.

### BRIEF DESCRIPTION OF THE DRAWINGS

The accompanying drawings, which are incorporated herein and constitute a part of this disclosure, illustrate exemplary embodiments and, together with the description, are used to explain the disclosed principles. In these drawings, where appropriate, reference numerals that illustrate the same or similar structures, components, materials, and/or elements in different figures are labeled similarly. It is understood that various combinations of the structures, components, and/or elements, other than those specifically shown, are contemplated and are within the scope of the present disclosure.

For simplicity and clarity of illustration, the figures depict the general structure of the various described embodiments. Details of well-known components or features may be omitted to avoid obscuring other features, since these omitted features are well-known to those of ordinary skill in the art. Further, features in the figures are not necessarily drawn to scale. The dimensions of some features may be exaggerated relative to other features to improve understanding of the exemplary embodiments. One skilled in the art would appreciate that the features in the figures are not necessarily drawn to scale and, unless indicated otherwise, should not be viewed as representing dimensions or proportional relationships between different features in a figure. Additionally, even if it is not expressly mentioned, aspects described with reference to one embodiment or figure may also be applicable to, and may be used with, other embodiments or figures.

FIG. 1 is a schematic top view of an exemplary apparatus used to remove a double-sided coating from an edge of a substrate;

FIGS. 2A-2B are different views of an exemplary vacuum chuck assembly of the apparatus of FIG. 1;

FIG. 3A is a perspective view of an exemplary multi-head nozzle assembly of the apparatus of FIG. 1;

FIG. 3B is a perspective view of a single nozzle head of the nozzle assembly of FIG. 3A, consistent with some embodiments of the current disclosure;

FIG. 3C is a cross-sectional side view of the nozzle head of FIG. 3B, consistent with some embodiments of the current disclosure;

FIG. 4 is a schematic illustrating an exemplary use of the nozzle head of FIG. 3B, consistent with some embodiments of the current disclosure;

FIG. 5 is a side view of an exemplary nozzle assembly of the apparatus of FIG. 1; and

FIG. 6 is a flow chart illustrating an exemplary method of using the apparatus of FIG. 1.

### DETAILED DESCRIPTION

All relative terms such as “about,” “substantially,” “approximately,” etc., indicate a possible variation of ±10% (unless noted otherwise or another degree of variation is specified). In some cases, the specification also provides context to some of the relative terms used. For example, a feature (e.g., a coating edge, etc.) described as having a substantially sharp or substantially step-like configuration or shape (e.g., [symbol] -shape, [symbol] ) may deviate by ±10% from being perfectly step-like (e.g., a shape having rounded corners, such as, for example, [symbol] etc.) Further, a range described as varying from, or between, 5 to 10 (5-10), includes the endpoints (i.e., 5 and 10).

Unless otherwise defined, all terms of art, notations, and other scientific terms or terminology used herein have the same meaning as commonly understood by persons of ordinary skill in the art to which this disclosure belongs. Some components, structures, and/or processes described or referenced herein are well understood and commonly employed using conventional methodology by those skilled in the art. These components, structures, and processes will not be described in detail. All patents, applications, published applications and other publications referred to herein as being incorporated by reference are incorporated by reference in their entirety. If a definition or description set forth in this disclosure is contrary to, or otherwise inconsistent with, a definition and/or description in these references, the definition and/or description set forth in this disclosure controls over those in references incorporated by reference. None of the references described or referenced herein is admitted as prior art relative to the current disclosure.

The discussion below describes an exemplary apparatus and method used to simultaneously remove a coating from the top and bottom surfaces of a substrate (e.g., wafer, panel, etc.) from an edge (or the edge zone) of the substrate. It should be noted that the specific features of the described apparatus are not limitations. Instead, embodiments of the described apparatus may be used to remove any coating(s) from any substrate in any suitable application. For example, the disclosed apparatus and method may be used to remove any type of coating (organic, inorganic, metallic, etc.) from any type of substrate.

The term substrate refers to the base material on which semiconductor or photonic devices or circuits are fabricated. In the discussion below, the term “substrate” is used broadly to refer to any component having a relatively flat surface upon which a coating may be disposed (conformally, as patches, in regions, etc.). For example, as used herein, a substrate includes a plate, a panel (e.g., a glass panel used in LCD manufacturing, semiconductor packaging, photomask manufacturing, etc.), a semiconductor wafer (e.g., a silicon wafer used to fabricate IC devices), a wafer with multiple IC devices formed thereon, a single IC device, a part (e.g., ceramic, organic, metallic, etc.) with one or more coatings formed or disposed thereon, etc.

A “coating” is a thin layer of material formed on the surface (front surface and/or back surface) of the substrate. This coating serves various purposes such as protection, insulation, conductivity enhancement, or altering surface properties for specific applications. The coating material depends on the desired function and may include metals, oxides, polymers, or other specialized compounds. The coating may be formed using techniques like physical vapor deposition, chemical vapor deposition, spin coating, or sputtering, ensuring uniform coverage and adherence to the substrate. As used herein, the term “coating” collectively refers to a coating formed of a single material and a multi-layer coating with multiple layers formed of different materials. The term “double-sided” coating is used to refer to a coating formed on the top and bottom surfaces (or the front and back surfaces) of the substrate. The coating on the top and bottom surfaces may be formed on the same material or of different materials.

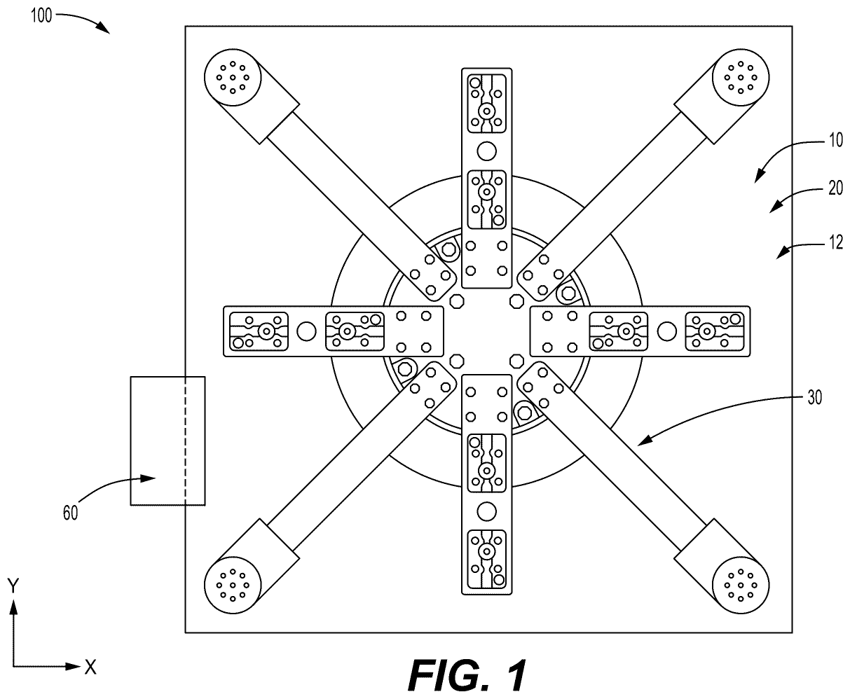

FIG. 1 is a schematic illustration of the top view of an exemplary apparatus 100 that may be used to remove a double-sided coating 20 from an edge 12 of a substrate 10. During deposition of the coating 20, the layer of material along the edges 12 may be uneven. Apparatus 100 may be configured to simultaneously remove (e.g., etch) the coating 20 from the top and bottom surfaces of the substrate 10 along the edges of the substrate such that the edge of the coating post etching is straight and clean (e.g., with minimal debris and excess chemicals). Apparatus 100 includes one or more multi-head nozzle assemblies 60A, 60B configured to etch the double-sided coating 20 from the substrate edges and a vacuum chuck assembly 30 configured to support the substrate 10 during the etching process.

In some embodiments, apparatus 100 may include only a single multi-head nozzle assembly, while in other embodiments, apparatus 100 may include multiple multi-head nozzle assemblies to simultaneously remove the coating 20 from multiple edges of the substrate 10. For example, with reference to FIG. 1, nozzle assembly 60A may remove the coating 20 from side AB while nozzle assembly 60B simultaneously remove the coating from side CD. After coating 10 is removed from sides AB and CD, the chuck assembly 30 may rotate with the substrate 10 (e.g., by 90°) for the nozzle assemblies 60A, 60B to remove the coating 20 from sides BC and AD. The nozzle assemblies 60A, 60B may move away from the substrate 10 (e.g., in the X direction) prior to substrate rotation, and then move in the opposite direction to reengage with the substrate 10 after rotation. Nozzle assemblies 60A and 60B may be mounted on X and Y actuators to facilitate their movement in the X and Y directions. In the discussion below, nozzle assembles 60A and 60B will be collectively referred to as nozzle assembly 60.

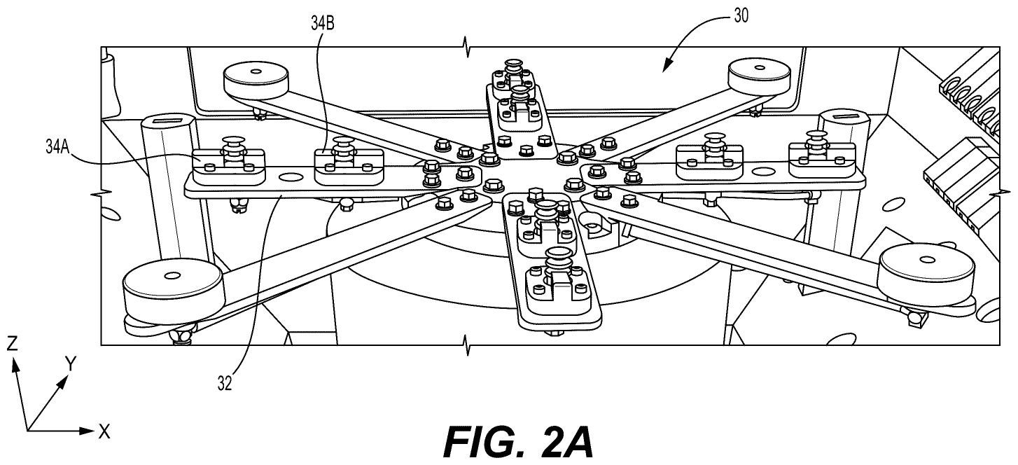

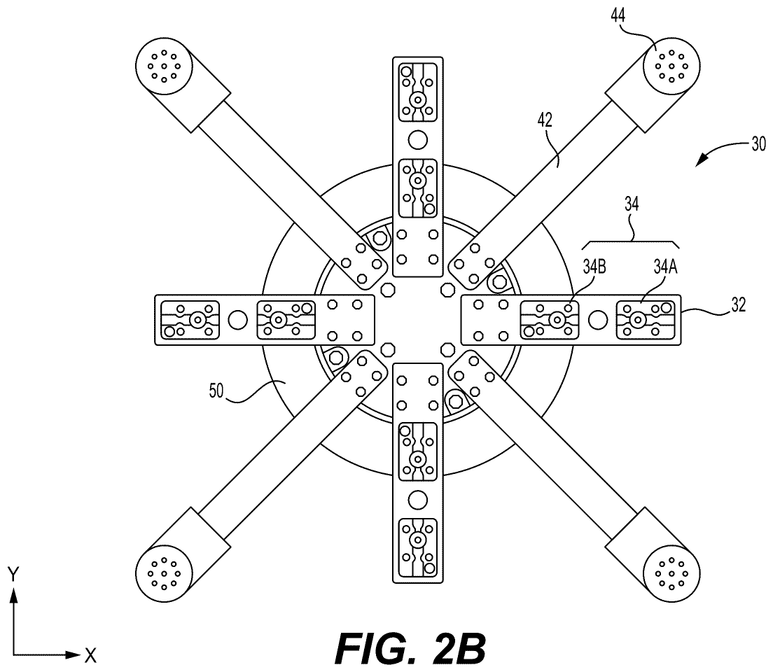

FIGS. 2A and 2B illustrate a perspective view and a top view, respectively, of an exemplary vacuum chuck assembly 30. Chuck assembly 30 includes a plurality of first arms 32 and a plurality of second arms 42 that extends radially outwards from a central hub 50 (e.g., like spokes of a wheel). Chuck assembly 30 may be configured to move up and down in the Z direction along a central axis 102 and rotate (clockwise or counterclockwise) about the central axis 102. Although not shown in the figures, chuck assembly 30 may be coupled to actuators and motors to facilitate its movement in the Z direction and rotation about the Z-axis (e.g., central axis 102).

In general, chuck assembly 30 may include any number of first and second arms 32, 42. The first arms 32 may be equally spaced apart from each other, and the second arms 42 may be equally spaced apart from each other. In other words, the angular spacing between adjacent arms of the plurality of first arms 32 may be substantially the same, and the angular spacing between the adjacent arms of the plurality of second arms 42 may be substantially the same. In some embodiments, the first and second arms 32, 42 may be equally spaced apart. In other words, the angular spacing between any two adjacent arms 32, 42 may be substantially the same. Arms 32 and 42 may be made of any material (plastic, metal, etc.). In some embodiments, the arms 32, 42 may be made of reinforced plastic.

In the exemplary embodiment illustrated in FIGS. 2A and 2B, chuck assembly 30 includes four substantially similar first arms 32 and four substantially similar second arms 42 angularly spaced apart from each other by about 45°. However, this is only exemplary. Each first arm 32 includes one or more vacuum cups 34 attached thereto. Vacuum cups 34 may be devices or attachments configured to grip and hold objects (e.g., substrate 10) using suction generated by a vacuum (see, e.g., FIG. 1). In some embodiments, the vacuum cups 34 may be made from a flexible material (e.g., rubber, silicone, etc.) and include a hollow structure with an opening that is configured to mate with a flat surface (e.g., the top or bottom surface) of the substrate 10. Collectively, the vacuum cups 34 on the first arms 32 may securely grip and hold the substrate 10 by creating suction between the cups 34 and the substrate surface. Any number of vacuum cups 34 may be provided on each first arm 32. In general, the number of vacuum cups 34 (on each arm 32) may depend on the size of the substrate 10. When a plurality of vacuum cups 34 are provided on each arm 32, they may be radially spaced apart on the arm 32. For example, in the exemplary embodiment illustrated in FIGS. 2A and 2B, each first arm 32 includes two vacuum cups 34A and 34B radially spaced apart from each other.

Each second arm 42 may include one or more shower-heads 44 configured to provide an air cushion under the surface (e.g., bottom surface) of the substrate 10 held by the vacuum cups 34 (of arms 32). In the embodiment of FIGS. 2A and 2B, a single shower-head 44 is provided at the radially outer-most end of each second arm 42. However, this is only exemplary, and in general, each second arm 42 may include any number of shower-heads 44 radially spaced apart on the arm 42. Each shower-head 44 may be fluidly coupled to a source of pressurized air (or another gas). Although not a requirement, in some embodiments, the second arms 42 may include a conduit that directs the pressurized air to the shower-heads 44. The shower-heads 44 may include a perforated plate with grid-like pattern of small holes (or perforations) that dispenses the pressurized air evenly in an area under the substrate 10 disposed over the shower-heads 44. When the substrate 10 is supported on chuck assembly 30 (see FIG. 1), the vacuum cups 34 attached to the first arms 32 grips and holds the substrate 10 securely (to the chuck assembly 30) while the pressurized air from the shower-heads 44 forms an air cushion that levitates the corners of the substrate and prevents it from sagging (or bending in the −Z direction) due to its weight. Preventing the substrate 10 from bending downwards ensures that parts of the chuck assembly 30 (or parts of apparatus 100) do not contact the exclusion zone of substrate 10. The exclusion zone is an area along the edges or corners of the substrate where contact is disallowed during processing (e.g., for structural integrity, safety, or functionality of the substrate).

The lengths (e.g., length along a radial axis) of the first and second arms 32, 42 may depend on the specific application (e.g., size and shape of substate 10). However, in general, the second arms 42 may be longer (or have a greater length) than the first arms 32. For example, when substrate 10 is a square or rectangular panel (see FIG. 1), the shower-heads 44 on the opposite ends of the diagonally-extending second arms 42 may ensure that the diagonal ends (e.g., corners) of the substrate 10 does not bend down when the substrate 10 is supported by the vacuum cups 34 on the first arms 32. The size and characteristics (number and size of perforations, etc.) of the shower-heads 44 may also depend on the application (e.g., weight of substrate 10, etc.). In embodiments of the current disclosure, the number of holes, the pattern of the holes, and the pressure of the air discharged through these holes are designed such that the air cushion formed by the shower-heads 44 are configured to lift (e.g., levitate) glass panels having a thickness between about 0.2-3.4 mm.

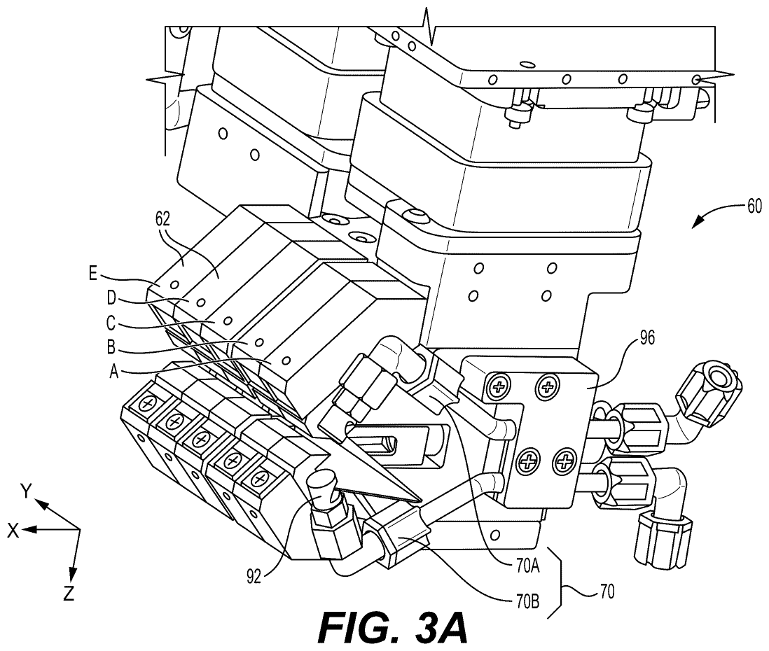

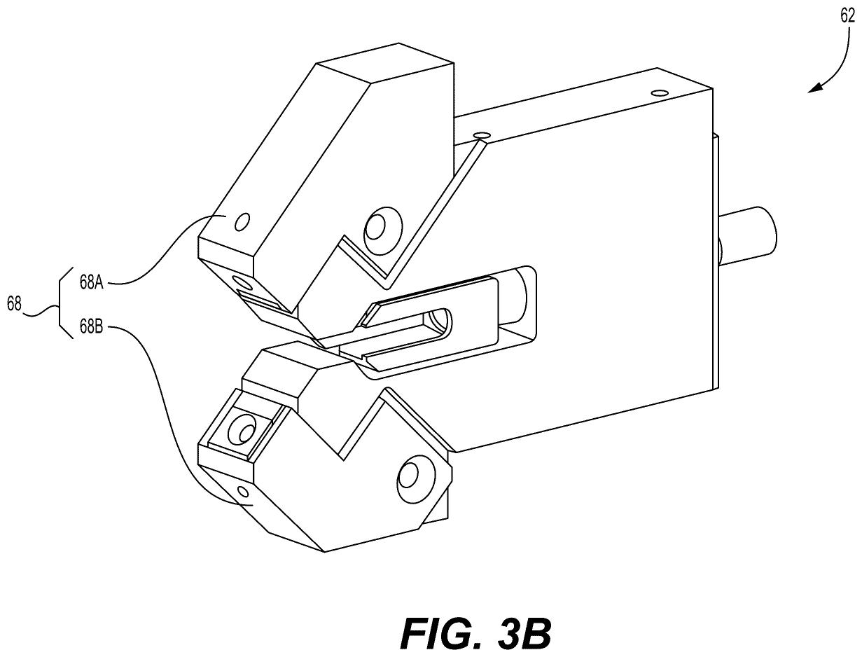

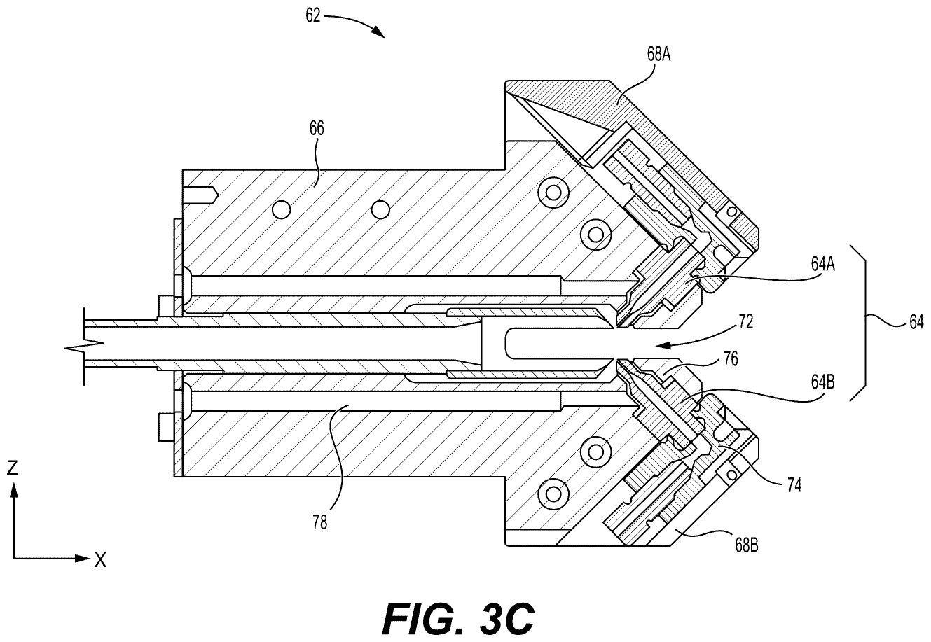

When the substrate 10 is supported on chuck assembly 30, the coating 20 on the edges of the top and bottom surfaces of the substrate 10 is etched and removed using the multi-head nozzle assembly 60 of apparatus 100 (see FIG. 1). FIG. 3A is a perspective view of an exemplary multi-head nozzle assembly 60 of apparatus 100. In some embodiments, nozzle assembly 60 is made up of multiple nozzle heads 62 arranged side-side (e.g., stacked in parallel) to increase throughput (e.g., to increase the length of the coating that may be removed). In the exemplary embodiment illustrated in FIG. 3A, five nozzle heads 62 are shown stacked along the Y-axis. However, this is only exemplary, and in some embodiments, nozzle assembly 60 may only include a single nozzle head 62. In general, nozzle assembly 60 may include any number (e.g., 1-12) of nozzle heads 62.

In addition to the nozzle heads 62, a pair of air nozzles 70 may be positioned on one side of the stacked nozzle heads 62. The pair of air nozzles 70 includes a first air nozzle 70A and a second air nozzle 70B positioned on opposite sides of the substrate 10 being processed by apparatus 100. The first air nozzle 70A is configured to direct a stream (or jet) of air (e.g., clean dry air (CDA), nitrogen, another inert gas, etc.) on one surface (e.g., top surface) of the substrate 10, and the second air nozzle 70B is configured to direct a similar air stream to the opposite surface (e.g., bottom surface) of the substrate 10. In some embodiments, a pair of air nozzles 70 may be positioned on both sides of the stacked nozzle heads 62.

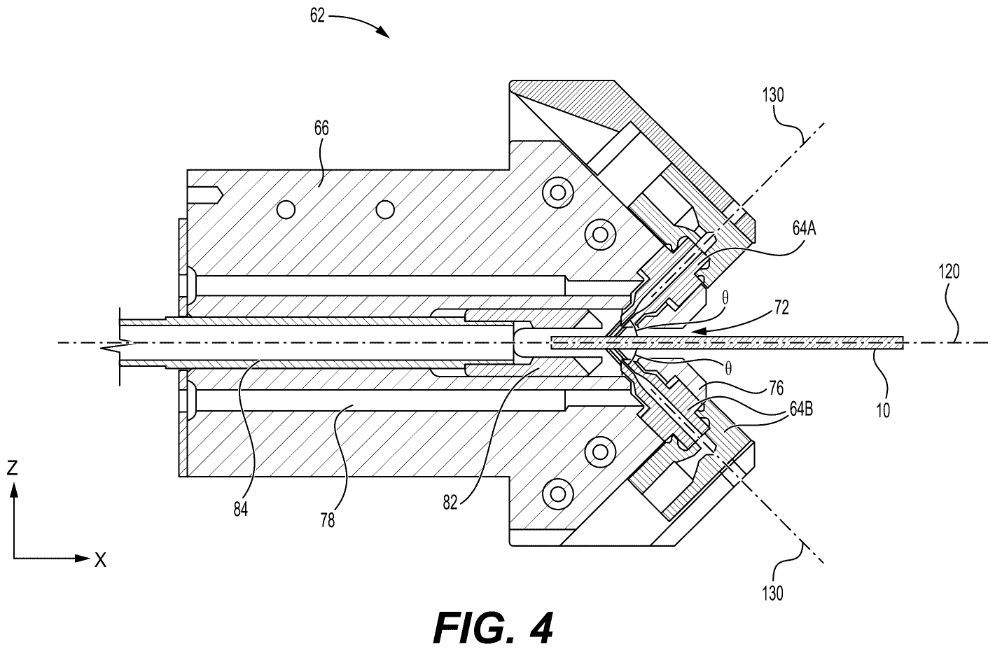

FIGS. 3B and 3C illustrate a perspective view and a cross-sectional side view, respectively, of a single nozzle head 62 of nozzle assembly 60. FIG. 4 is a schematic illustration of a substrate 10 being processed by nozzle head 62. In the discussion below, reference will be made to FIGS. 3B, 3C, and 4. Nozzle head 62 includes a nozzle body 66 with a central cavity 72 that extends into the body 62. When multiple nozzle heads 62 are assembled to form nozzle assembly 60, the cavities 72 of the multiple nozzle heads 62 align to form a slot that is configured to receive the edge of the substrate 10 supported by vacuum chuck assembly 30 therein (see FIG. 4). Nozzle head 62 includes a pair of nozzle holders 68A and 68B (collectively 68) positioned on opposite sides of the central cavity 72. Each nozzle holder 68 supports a nozzle tip 64 that is configured to direct a chemical composition (e.g., a liquid etchant) on a surface of the substrate 10 received in cavity 72. For example, a first nozzle tip 64A directs a stream of the etchant to the top surface of the substrate 10 to etch the coating 20 (at the edge) on the top surface, and a second nozzle tip 64B directs a stream of the etchant to the bottom surface of substrate 10 to similarly etch the coating 20 on the bottom surface. A cover plate 74 may engage with the nozzle holder 68 and the body 66 to securely support each nozzle tip 64 in nozzle head 62. The nozzle holder 68 and the cover plate 74 (and/or body 66) may include conduits configured to direct the liquid etchant to the nozzle tip 64 to be discharged on the substrate 10. As will be described in more detail later, although described as an etchant, any suitable liquid (e.g., DI water, etchant, etc.) may discharged through the nozzle tips 64 of nozzle head 62.

An annular space between the nozzle tip 64 and the body 66 defines a duct 76 that is configured to direct a shroud (or a curtain) of high-pressure gas (e.g., nitrogen gas) around the etchant (or chemical composition) emanating from the nozzle tip 64. A conduit 78 extending through the body 66 directs a supply of nitrogen gas discharged through the duct 76. Discharging a shroud of high-pressure gas around the liquid etchant stream emanating from the nozzle tip 64 assists in etching the coating along a straight line with a sharp, well-defined edge. The high-pressure gas shroud may form a protective and confining barrier around the liquid etchant stream as it exits the nozzle tip 64 and help to contain and focus the liquid etchant, thereby preventing it from spreading beyond the desired etching area. As a result, the etchant may be guided along a more controlled and defined path. The gas shroud may also apply additional force and directionality to the etchant stream through aerodynamic effects. For example, the high-pressure gas may surround and push the liquid stream, thereby enhancing its momentum and directing it toward the substrate surface in a more concentrated manner. This aerodynamic assistance may contribute to achieving a straighter and more uniform etching line. Enveloping the liquid etchant stream with high-pressure gas may also help to minimize edge smearing or feathering that can occur due to fluid turbulence or diffusion. For example, the gas barrier maintains the integrity of the etchant stream and allows it to maintain a sharp and well-defined edge profile as it contacts the substrate surface.

Nozzle head 62 also includes a suction cup 82 disposed within central cavity 72. The suction cup 82 is connected to a drainpipe 84 coupled to a vacuum pump. During operation of apparatus 100, the suction provided by the in-build suction cup 82 removes the etchants (and the removed coating) sprayed by the nozzle tip 64. The nitrogen curtain around the liquid etchant stream helps in pushing the etchants into the suction cup 82. It should be noted that although nitrogen gas is described as being used as a shroud to surround the etchant stream (discharged through the nozzle tip 64), this is only exemplary. In general, any suitable gas (e.g., an inert gas) may be used.

With reference to FIG. 4, the nozzle tips 64 of nozzle head 62 are inclined with respect to the substrate 10 such that the liquid stream emanating from these nozzle tips 64 impinge on the substrate surfaces at an angle (e.g., an obtuse angle) to push the liquid along with the removed coating material (e.g., debris) towards the suction cup 82. In general, nozzle tips 64 may be inclined at any angle such that the liquid stream from these tips are angled (or directed) towards the suction cup 82. A longitudinal axis 130 of each nozzle tip 64 may be inclined at an angle (θ) with a plane 120 of the substrate surface (see FIG. 4). The angle of inclination (θ) may be between about 30-60 degrees. In some embodiments, the angle of inclination (θ) may be between about 40-50 degrees (or about 45 degrees in some embodiments). Directing a stream of the etchant (on the substrate surface) angled towards the suction cup 82 assists in removal of the etching waste products (via suction cup 82) without splashing and spreading on the substrate surface. Additionally, directing an angled jet of the etchant onto a coated substrate surface may offer a more controlled, efficient, and precise method of coating removal and may be particularly beneficial for applications requiring intricate surface treatment and uniform results.

As mentioned previously, although an etchant is described as being discharged through the nozzle tip 64, this is only exemplary. In general, any liquid may be discharged through the nozzle tip 64. For example, in some embodiments, DI water may be discharged through the nozzle tips 62 of some nozzle heads 62 (of nozzle assembly 60) while a suitable etchant may be discharged through other nozzle heads 62. For example, with reference to the nozzle assembly 60 of FIG. 3A, in some exemplary embodiments, the outermost nozzle head 62 (marked A) closest to the pair of air nozzles 70 may discharge DI water while the other nozzle heads 62 (marked B-E) may discharge an etchant. In such an embodiment, when the nozzle assembly 60 traverses in the +Y direction along the substrate edge while removing its coating, the etchant discharged by the nozzle tips 64 of nozzle heads B-E will etch the coating on the substrate surface and the DI water discharged through nozzle head A will rinse the substrate surface. The air directed through the pair of air nozzles 70 may then dry the substrate surface. It should be noted that the above-described scenario is only exemplary. In general, nozzle heads 62 of nozzle assembly 60 may selectively discharge an etchant or DI water.

Typically, the type of liquid etchant (or chemical composition) discharged through a nozzle head 62 may depend on the application (e.g., the coating to be removed). For example, when a copper coating is to be removed from substrate 10, the chemical composition used may be one or more (e.g., a combination) of—a combination of sulfuric acid and hydrogen peroxide, nitric acid, citric acid, ammonium persulfate, cupric chloride, ferric chloride, or another commercially available etchant. As another example, when a titanium coating is to be removed, the chemical composition directed through the nozzle head 62 may be one or more of—hydrofluoric acid, nitric acid with hydrofluoric acid, potassium hydroxide, ammonium fluoride, chlorine-based etchants, or another commercially available etchant. It should be noted that the specific chemistries described above are merely exemplary. In some embodiments, the etchant used may provide high selectivity to different coatings and other materials that may be present in the substrate 10 (e.g., Si, EMC, Polyimide, SiO₂, etc.).

The type of gas discharged through the duct 76 to form a shroud around the liquid stream through nozzle tip 64 may also depend on the application. In general, any gas (e.g., air, N₂, an inert gas, etc.) may be discharged through the duct 76. In some embodiments, the liquid etchant (or DI water) discharged through the nozzle tips 64 may be heated. Additionally, or alternatively, in some embodiments, the gas discharged through duct 76 may be heated. In some embodiments, heaters may be coupled to the nozzle heads 62 to heat the etchant (and/or DI water) discharged through the nozzle tips 64 and/or the gas discharged through ducts 76. In some embodiments, the liquid (e.g., etchant and DI water) and the gas discharged through the nozzle heads 62 may be pressurized.

The materials of nozzle head 62 are selected to withstand the chemicals (e.g., etchant and gas) discharged through the nozzle head. The specific materials used may depend upon the application. In some exemplary embodiments, the nozzle tip 64 may be made of Quartz, and the nozzle body 66 may be made of Polyvinylidene Fluoride (PVDF) or another suitable thermoplastic polymer. In some embodiments, nozzle holder 68 and cover plate 74 may be made of titanium. It should be noted that these specific materials are merely exemplary.

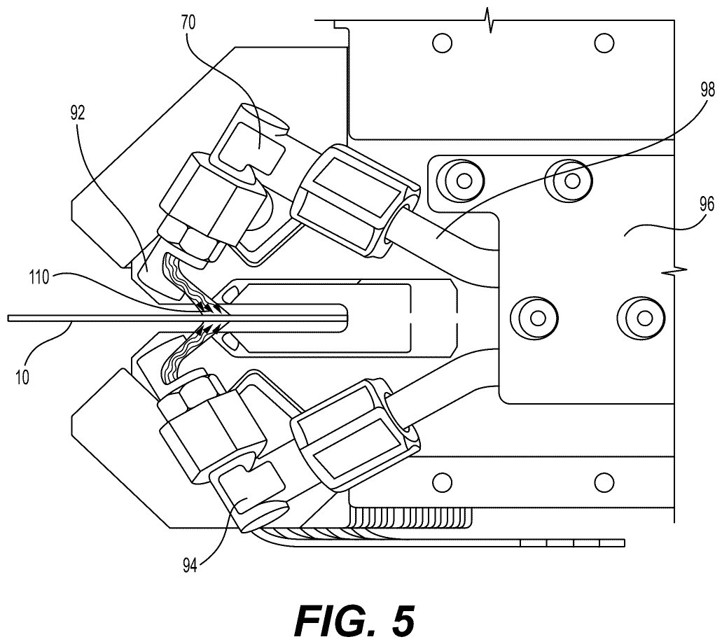

With reference to FIG. 3A, the pair of air nozzles 70 of nozzle assembly 60 is configured to dry the etched and rinsed substrate 10 by discharging a stream of air (e.g., CDA, N₂ gas, or another suitable gas) to form an air knife along the top and bottom sides of the edge of the substrate 10 to remove the residues after the etch and rinse steps of the process. FIG. 5 illustrates an exemplary embodiment of air nozzles 70. Each air nozzle 70 may include a fan spray nozzle 92 of suitable spray angle that discharges a high velocity stream of air (e.g., an air knife 110) and an elbow connection 94 that allows for rotation of the spray nozzle 92 around different axes. The pair of air nozzles 70 may be connected to a mounting block 96 via a flexible tube 98 that allows for linear and rotational adjustments of the air nozzles 70. In some embodiments, apparatus 100 may be incorporated in a fully automated tool with the apparatus 100 being positioned in a process module. In such embodiments, a robot may pick up a substrate (e.g., substrate 10) for processing from a load port of the tool and place it on the vacuum chuck assembly 30 of apparatus 100 positioned in the process module for coating removal.

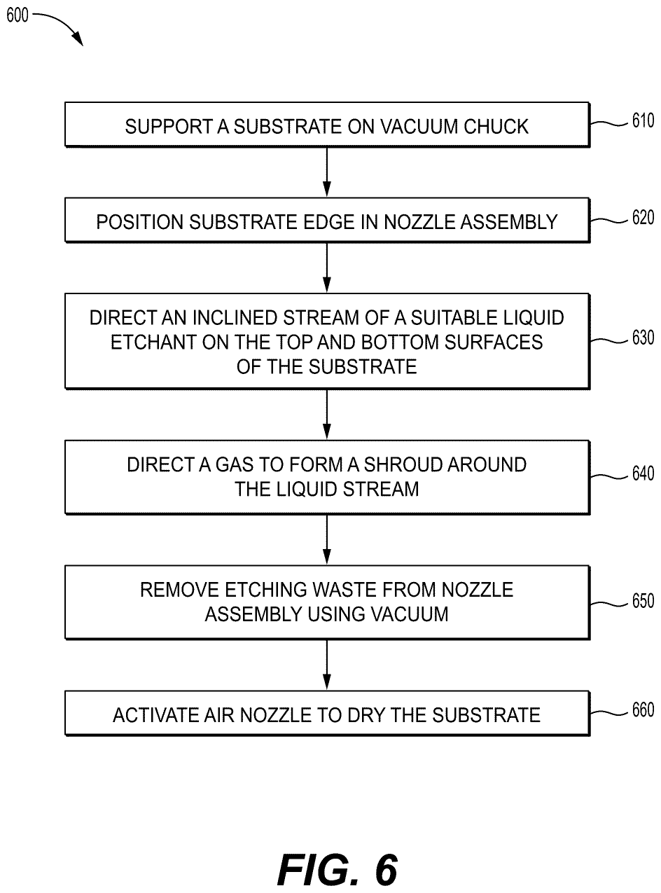

An exemplary method 600 of using an apparatus 100 of the current disclosure will now be described with reference to FIG. 6. In step 610, a substrate 10 may be supported on the chuck assembly 30. When the substrate is positioned on the chuck assembly 30, the vacuum cups 34 on the first arms 32 may hold the substrate 10 in position using suction. The shower-heads 44 on chuck assembly 30 may also activate to form a cushion of air under the substrate corners to prevent it from sagging and contacting any part of chuck assembly 30. In some embodiments, the shower-heads 44 are activated to form the air cushions at the same time (or even before in some embodiments) the substrate is placed on chuck assembly 30. In step 620, the chuck assembly 30 may move (e.g., lift, move sideways, etc.) to position an edge of the substrate 10 within the aligned central cavities 72 of the nozzle heads 62 of nozzle assembly 60.

In step 630, an inclined and pressurized stream of a suitable liquid etchant (heated in some embodiments) is discharged through the nozzle tips 64 of nozzle assembly 60 on the top and bottom surfaces of the substrate 10. In step 640, a pressurized gas (heated in some embodiments) is directed through the annular ducts 76 around the nozzle tips 64 to form a shroud (or curtain) of gas around the liquid stream emanating from the nozzle tips 64. The gas shroud around the liquid stream assists in focusing the liquid stream to a tightly defined spray area on the substrate surface. In some embodiments, in step 630, some nozzle heads 62 (e.g., nozzle heads B-E of FIG. 3A) of the nozzle assembly 60 may discharge the etchant to etch the coating on the substrate surface, while other nozzle heads 62 (e.g., nozzle head A of FIG. 3A) discharge DI water to rinse the substrate surface after etching. In some embodiments, the nozzle assembly 60 and/or the substrate 10 may be translated such that the etchant stream with its gas shroud traces a path along the substrate edge and removes the coating along the path. For example, with reference to FIG. 1, nozzle assembly 60A (and/or 60B) may be moved in the Y direction from (A→B or B→A) to remove the coating from edge AB.

In step 650, the in-build suction cups 82 of the nozzle assembly 60 is activated to remove the sprayed etchant and particles of the removed coating (e.g., etching waste) from the nozzle assembly 60. Directing an inclined stream of the etchant (and DI water) from the nozzle heads 62 towards the suction cups 82 (in step 630) assists in quickly removing the etching waste from the nozzle assembly 60 without splashing or spreading on the substrate 10. In step 660, air nozzles 70 of the nozzle assembly 60 may be activated to direct a stream of air (e.g., CDA or N₂) on the top and bottom surfaces of the substrate 10 to remove residues and dry the substrate after etching and rinsing.

As explained previously, in some embodiments, as illustrated in FIG. 1, apparatus 100 may include multiple multi-head nozzle assemblies (e.g., a pair of nozzle assemblies 60A, 60B) to simultaneously remove the coating 20 from multiple sides (AB, CD, etc.) of the substrate 10. In such embodiments, in steps 620-660, nozzle assembly 60A removes the coating 20 from side AB while nozzle assembly 60B simultaneously removes the coating from side CD. After the coating is removed from sides AB and CD, the nozzle assemblies 60A, 60B retract (e.g., moves in the X direction away from the substrate) and the vacuum chuck assembly 30 rotates (about axis 102 clockwise or counterclockwise) with the substrate 10 (e.g., by 90°) such that sides BC and AD (of the substrate) now face nozzle assemblies 60A, 60B. Nozzle assemblies 60A and 60B now move towards the substrate to engage with the substrate edges and remove the coating 20 from sides BC and AD (using steps 620-660).

In general, the above-described steps may be performed in any order. In some embodiments, some of the described steps may be combined together. In some embodiments, an exemplary method of using the apparatus 100 may include additional steps not illustrated in method 600. For example, after etching one edge, the substrate and/or the apparatus 100 may be rotated to etch other edges of the substrate 10. As another example, when apparatus 100 is incorporated in a tool, the method may include steps, such as, a pick-and-place robot picking a substrate from a load port and placing it on the vacuum chuck assembly of apparatus 100 in preparation for etching, a robot removing the substrate after etching in apparatus 100 and moving it another process module for additional processing.

Although the current disclosure is described as being used to remove a coating from an edge of a substrate, this is only exemplary. For example, apparatus 100 may be used to remove a coating from any region (e.g., center, side, etc.) of a coated substrate. Persons of ordinary skill in the art would recognize that the disclosed apparatus can be used for any application (e.g., to remove paint from the surface of a component, a metallic or polymeric coating from the surface of a ceramic/organic substrate or a semiconductor wafer, etc.). Furthermore, although in the description above, some features were disclosed with reference to specific embodiments, a person skilled in the art would recognize that this is only exemplary, and the features are applicable to all disclosed embodiments. Other embodiments of the apparatus, its features and components, and related methods will be apparent to those skilled in the art from consideration of the disclosure herein.

What is claimed is:

1. An apparatus to remove at least a portion of a coating from an edge of a substrate, comprising:
a vacuum chuck assembly configured to support the substrate, wherein the vacuum chuck assembly includes a plurality of vacuum cups configured to hold the substrate using suction; and
a nozzle assembly including one or more nozzle heads, wherein each nozzle head of the one or more nozzle heads includes,
a body having a cavity, the cavity being configured to receive the edge of the substrate therein;
a suction cup positioned within the cavity, wherein the suction cup is configured to be coupled to a vacuum pump;
a pair of nozzle tips supported on the body and positioned on opposite sides of the cavity, wherein the pair of nozzle tips are each inclined towards the suction cup and configured to direct an angled stream of a liquid on a surface of the substrate received in the cavity; and
an annular duct defined around each nozzle tip of the pair of nozzle tips, wherein the annular duct is configured to discharge a pressurized gas to form a gas shroud around the angled stream of liquid.

2. The apparatus of claim 1, wherein each nozzle tip of the pair of nozzle tips is inclined at an angle between 30-60 degrees with a surface of the substrate.

3. The apparatus of claim 1, wherein the nozzle assembly includes a plurality of nozzle heads arranged side-to-side along the edge of the substrate.

4. The apparatus of claim 1, wherein the pair of nozzle tips include a first nozzle tip and a second nozzle tip, and wherein the first nozzle tip is configured to direct a first angled stream of the liquid on a top surface of the substrate and the second nozzle tip is configured to direct an angled stream of the liquid on a bottom surface of the substrate.

5. The apparatus of claim 1, wherein the nozzle assembly is configured to move along the edge of the substrate.

6. The apparatus of claim 1, wherein the vacuum chuck assembly includes a plurality of radially extending first arms equally spaced apart from each other, wherein the plurality of vacuum cups are arranged on the plurality of radially extending first arms.

7. The apparatus of claim 6, wherein each first arm of the plurality of radially extending first arms includes multiple vacuum cups spaced apart from each other.

8. The apparatus of claim 6, wherein the vacuum chuck assembly further includes a plurality of radially extending second arms equally spaced apart from each other, wherein each second arm of the plurality of radially extending second arms includes a shower-head configured to generate an air cushion under a region of the substrate supported by the vacuum chuck assembly, wherein the air cushion is configured to resist movement of the region towards the shower-head.

9. The apparatus of claim 8, wherein the plurality of first arms and the plurality of second arms are spaced apart from each other by about 45 degrees, and wherein the plurality of vacuum cups are positioned radially inwards of the shower-head on each second arm.

10. The apparatus of claim 1, wherein the vacuum chuck assembly includes a plurality of shower-heads, wherein each shower-head of the plurality of shower-heads is configured to discharge pressurized air under a corner region of the substrate to prevent the corner region from moving towards the shower-head.

11. The apparatus of claim 1, wherein the nozzle assembly further includes a pair of air nozzles arranged on one side of the one or more nozzle heads, wherein a first air nozzle of the pair of air nozzles is configured to direct an air stream onto a top surface of the substrate and a second air nozzle of the pair of air nozzles is configured to direct an air stream onto a bottom surface of the substrate.

12. An apparatus to remove at least a portion of a coating from an edge of a substrate, comprising:
a vacuum chuck assembly configured to support the substrate, wherein the vacuum chuck assembly includes,
a plurality of radially extending arms equally spaced apart from each other, wherein the plurality of radially extending arms includes a first set of arms and a second set of arms;
a plurality vacuum cups coupled to the first set of arms, wherein the plurality of vacuum cups are configured to hold the substrate using suction; and
a plurality of shower-heads coupled to the second set of arms, wherein the plurality of shower-heads are positioned radially outwards of the plurality vacuum cups and are each configured to discharge pressurized air under a corner region of the substrate; and
a nozzle assembly including a plurality of nozzle heads arranged side-to-side, wherein each nozzle head of the plurality of nozzle heads includes,
a body having a cavity, the cavity being configured to receive the edge of the substrate therein;
a suction cup positioned within the cavity, wherein the suction cup is configured to be coupled to a vacuum pump;
a pair of nozzle tips positioned on opposite sides of the cavity, wherein the pair of nozzle tips are each (i) inclined towards the suction cup and make an angle between about 30-60 degrees with a surface of the substrate, and (ii) configured to direct an angled stream of a liquid on a surface of the substrate received in the cavity; and
an annular duct defined around each nozzle tip of the pair of nozzle tips, wherein the annular duct is configured to discharge a pressurized gas to form a gas shroud around the angled stream of the liquid.

13. The apparatus of claim 12, wherein the nozzle assembly further includes a pair of air nozzles arranged on one side of the plurality of nozzle heads, wherein a first air nozzle of the pair of air nozzles is configured to direct an air stream onto a top surface of the substrate and a second air nozzle of the pair of air nozzles is configured to direct an air stream onto a bottom surface of the substrate.

14. The apparatus of claim 12, wherein each shower-head of the plurality of shower-heads is configured to discharge pressurized air under a corner region of the substrate to prevent the corner region from moving towards the shower-head.

15. The apparatus of claim 12, wherein the pair of nozzle tips include a first nozzle tip and a second nozzle tip, and wherein the first nozzle tip is configured to direct a first angled stream of the liquid on a top surface of the substrate and the second nozzle tip is configured to direct an angled stream of the liquid on a bottom surface of the substrate.

16. The apparatus of claim 12, wherein each arm of the first set of arms includes multiple vacuum cups spaced apart from each other.

17. The apparatus of claim 12, wherein each second arm of the plurality of second set of arms includes a shower-head coupled thereto, and each shower-head is configured to form an air cushion under a corner region of the substrate.

18. The apparatus of claim 12, wherein the nozzle assembly is configured to move along the edge of the substrate.

19. The apparatus of claim 12, wherein the plurality of radially extending arms of the vacuum chuck assembly are spaced apart from each other by about 45 degrees.

20. The apparatus of claim 12, wherein each nozzle tip of the pair of nozzle tips is inclined at an angle between 40-50 degrees with the surface of the substrate.
